(19) United States
(12) Patent Application Publication
(10) Pub. No.: US 2006/0092751 A1
(43) Pub. Date: May 4, 2006

(54) Peripheral management

(75) Inventors: Jeff M. Anderson, Camas, WA (US); Jeremy Bunn, Kelso, WA (US); Natalie I. Willson, Battle Ground, WA (US); Thomas James Logue, Vancouver, WA (US); Dora Rozis, Camas, WA (US)

Correspondence Address: SCHWEGMAN, LUNDBERG, WOESSNER & KLUTH, 1600 TCF TOWER, 121 SOUTH EIGHT STREET, MINNEAPOLIS, MN, 55402, US

(73) Assignee: Hewlett-Packard Development Company, L.P.

(21) Appl. No.: 10/982,002

(22) Filed: Nov. 4, 2004

(51) Int. Cl. G11C 8/02

(52) U.S. Cl. 365/232

(57) ABSTRACT

A peripheral management system includes a listing of a plurality of peripheral types and at least one driver associated with selected ones of the plurality of peripheral types.

### TECHNICAL FIELD

Various embodiments described herein relate to management of peripherals.

### BACKGROUND

Computer systems may be connected through one or more print servers to a peripheral device, such as a printer. Setting up and maintaining a single print server may be relatively simple, but when multiple print servers exist in an enterprise, the setup and maintenance of each print server may become time consuming and complicated.

### BRIEF DESCRIPTION OF THE DRAWINGS

FIG. 1 illustrates an example embodiment of a system including a host computer, a managed device, and a server coupled through a network.

FIG. 2 illustrates an example embodiment of a system including one or more host computers, one or more managed devices, and one or more servers on the network.

FIG. 3 illustrates a peripheral server manager (PSM) and a peripheral driver manager (PDM), in an example embodiment.

FIGS. 4 and 5 illustrate example embodiments of the driver repository.

FIG. 6 illustrates an example embodiment of a server management page associated with the Peripheral Server Management.

FIGS. 7A and 7B illustrate an example embodiment of a results comparison page.

FIG. 8 illustrates an example embodiment of a process to compare a model peripheral server system and an actual peripheral server system.

### DETAILED DESCRIPTION

The term “peripheral” used herein may include printers, scanners, faxes, data transfer devices, gaming devices, televisions, cellular telephones, personal digital assistants (PDAs), workstations, data storage devices, digital video disk (DVD) drives, speakers, headphones, microphones, keyboards, input data controllers, vehicles, flash media players, any universal serial bus (USB) series connected devices, network interface, cell phone, telephony communication devices, audio and/or video devices, cameras, Motion Picture Experts Group-2, Audio Layer 3 (MP3) devices, radios, video players, modems, processors, application-specific modules, or any other electronic device, such as high-speed computers, and personal computers.

In some embodiments disclosed herein, a system includes a model peripheral infrastructure system, a current enterprise system, and an identification of areas in the current enterprise system that are out-of-sync with the model peripheral infrastructure system. The model peripheral infrastructure system may include a driver repository listing a plurality of peripheral types and at least one driver associated with a selected peripheral type. Changes may be implemented to the model peripheral infrastructure system and/or to the current enterprise system to synchronize the systems. Identification of the out-of-sync areas and the opportunity to implement appropriate changes may permit managing a variety of servers and/or peripherals in an efficient manner.

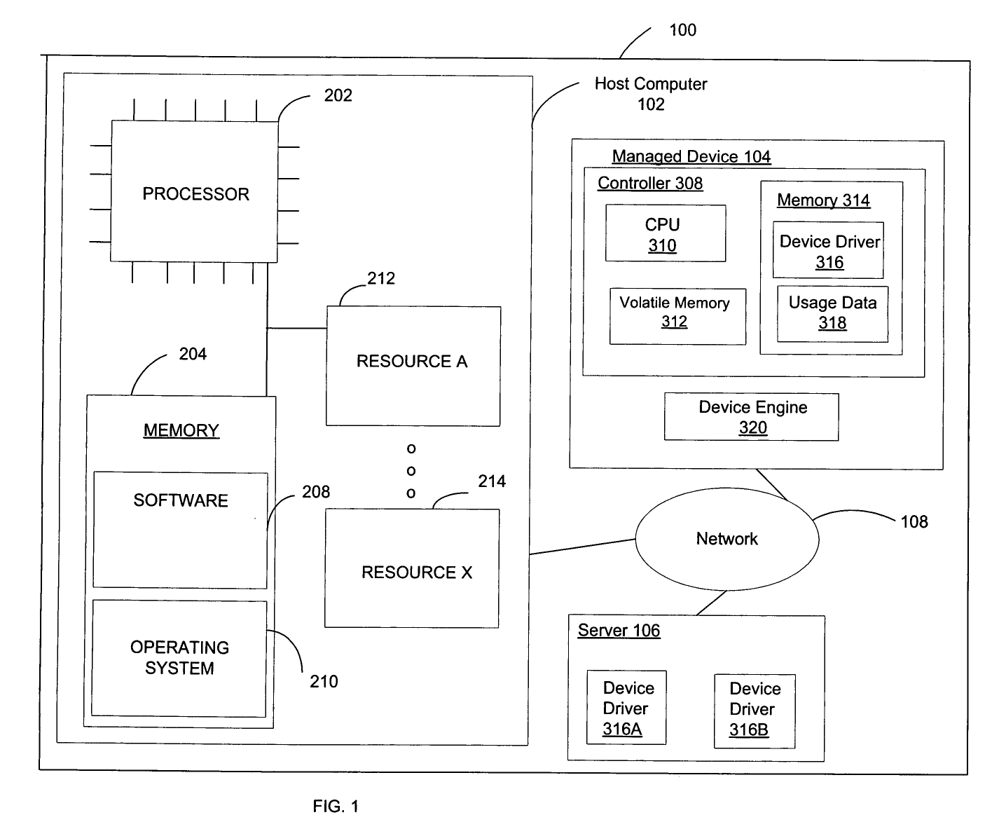

FIG. 1 illustrates an example embodiment of a system 100 that may include a host computer 102, a managed device 104, and a server 106 coupled through a network 108. The host computer 102, in turn, may include a processor 202, a memory 204, and one or more resources, such as resource A 212 and resource X 214. The memory 204 of the host computer 102 may include software 208 (e.g., application software) and an operating system 210.

The processor 202 may comprise a digital signal processor or processing unit of any type of architecture, such as an ASIC, CISC (Complex Instruction Set Computing), RISC (Reduced Instruction Set Computing), VLIW (Very Long Instruction Word), or hybrid architecture, although any appropriate processor may be used. The processor 202 executes instructions. The processor 202 may include a control unit that organizes data and program storage in memory, such as memory 204, and may operate to transfer data and other information in and out of the host computer 102 and, in some embodiments, to and from one or more network connections to a network 108.

The memory 204 may comprise one or more mechanisms for storing data. For example, the memory 204, in various embodiments, may include one or more of a read only memory (ROM), random access memory (RAM), magnetic disk storage media, optical storage media, flash memory devices, and/or other volatile and non-volatile machine-readable media. In other embodiments, the memory 204 may include any appropriate type of storage device or memory. Although one memory is shown, multiple memories of various types and multiple types of storage devices may be present.

The software 208 stored in the memory 204 may be operable on the processor 202 to cause the host computer 102 to perform various tasks or operations. Some such tasks include causing the host computer 102 to synchronize a current enterprise system with a model peripheral infrastructure system. Further detail of the software operation is provided below.

The operating system 210 stored in the memory 204 may control operation of the host computer 102 and a variety of applications. The operating system 210 is capable of performing many basic tasks, such as recognizing input from one or more input devices, sending output to a display, keeping track of files and directories within the memory 204, and controlling peripheral devices, such as resource A 212 and/or resource X 214.

The operating system 210 of host computer 102 may includes various operating systems 210 such as real-time, multi-user, multiprocessing, multitasking, and multithreading operating systems. Some examples of such operating systems include the Microsoft® Windows® family of operating systems, UNIX®, Linux®, the O/S 390 Enterpriser Server® operating system available from International Business Machines®, application specific operating systems, or virtually any other operating system.

The resources 212 and 214 may include virtually any type of system resource. The number of resources varies based on the particular implementation. Some embodiments include no resources, while other embodiments include one or more resources. Some such resources include peripheral devices such as video cards, Small Computer System Interface (SCSI) cards, wired or wireless network interface cards (NIC), a modem, or virtually any other peripheral device couplable to or integrated within a main-board or motherboard of the host computer 102. Other such resources include data items within the system such as data stored in the memory 204, data in a register of the processor 202, or any other data available on or through the host computer 102. Yet other such resources include applications, operating system elements or resources, machine-code commands, processor portions, or virtually any other resource of the host computer 102.

The managed device 104 may include a controller 308 for processing data from the one or more host computers 102 and/or from the one or more servers 106 coupled to the network 108. The controller 308 typically includes a data processing unit or CPU(s) 310, a volatile memory 312 (i.e., RAM), and a nonvolatile memory 314. The nonvolatile memory 314 can include various computer storage media such as ROM, flash memory, a hard disk, a removable floppy disk, a removable optical disk and the like. The nonvolatile memory 314 generally provides storage of computer readable instructions, data structures, program modules and other data for the managed device 104. The memory 314 may include a device driver 316 and usage data 318 that is accumulated over time by controller 308 as the managed device 104 performs various functions, such as printing.

The managed device 104 also includes a device engine 320 that may perform, if the managed device is a printer, for example, the actual printing of a document or may form an image onto a print medium. Thus, the controller 308 may process image/document data received as a job, such as a print job, from the host computer 102 and manages the device 104 functions by the engine 320.

The drivers 316 may be installed on the host computer 102, and may also be installed on the server 106. The server 106, such as a print server, may include one or more device drivers, shown as 316A and 316B. When the driver 316A is installed on the server 106, then all host computers 102, including those with various operating systems, such as Windows 95, Windows 98, Windows NT, or Windows ME, may have the driver installed when they connect to the server 106. The driver(s) 316A, 316B installed on the server 106 may be utilized by the host computers 102 or clients. The clients may download and install the driver(s) from the server 106 via a “Point ‘n’ Print” mechanism supported by server. The host computer 102 uses the appropriate driver 316 to generate a job, such as a print job or a customized document, in the appropriate format. The job may be configured in a page description language such as PCL (printer control language) or PostScript, for example, depending on the managed device 104. The job sent by the host computers and received by the server 106 is forwarded onto the managed device 104 through a queue 109. The managed device 104 may then receive the job and print the customized document.

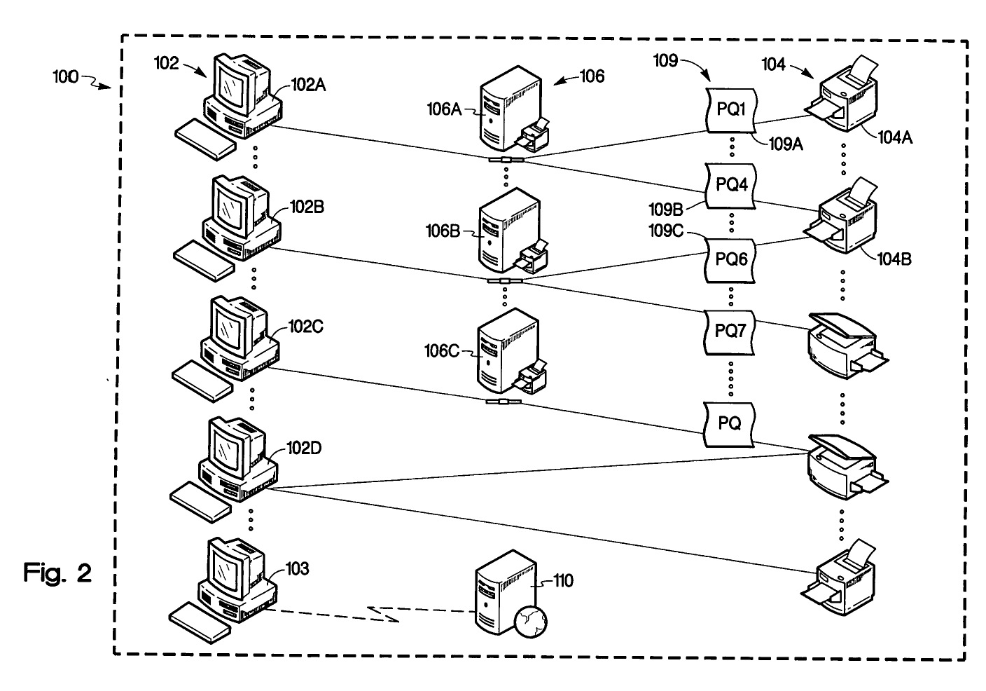

FIG. 2 illustrates an example embodiment of the system 100 including one or more host computers 102, one or more managed devices 104, and one or more servers 106 coupled to a network 108. As shown in the example embodiment of FIG. 2, the server 106 can manage one or more pending jobs by creating and maintaining one or more queues 109, such as print queues, for one or more managed device 104. Any queue 109 may be empty and waiting for jobs, or perhaps comprise a lineup of one or more jobs waiting to be processed in the managed device 104, such as jobs waiting to be printed.

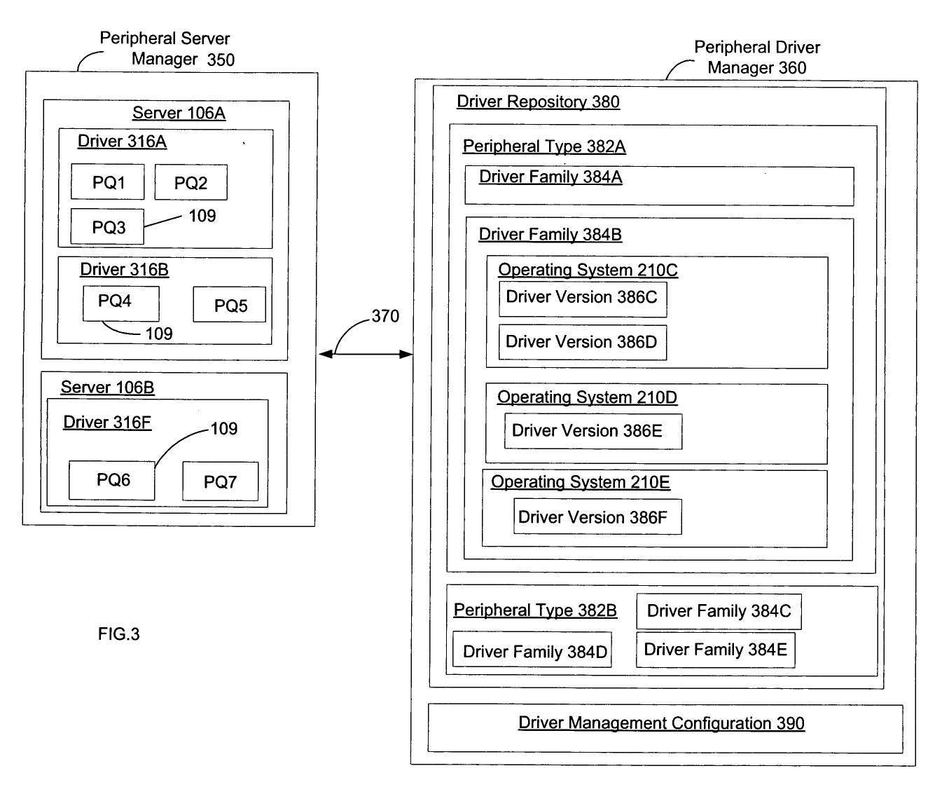

The host computer 102A is shown as associated with the server 106A, in this example embodiment. The server 106A is shown as associated with devices 104A and 104B. Print queue PQ1 109A is shown to be associated with device 104A. Print queue PQ4 109B is shown to be associated with device 104B. Print queues PQ2, PQ3, and PQ5, shown in FIG. 3, are shown to be associated with server 106A. The host computer 102B is shown to be associated with the server 106B, in this example embodiment. The server 106B may be associated with the device 104B and another device, for example a laser printer. Print queue PQ6 109C is shown to be associated with device 104B. Print queue PQ7 may be associated with the laser printer, for instance.

Associated with the device 104B, for example, there may be multiple queues, such as the queue 109B from the server 106A, and the queue 109C from the server 106B. Any queue may be shared by multiple users, including queues from other servers, for example server 106C, and/or queues from other computers, for example, host computer 102D. One or more queues, for example queue 109A and 109B, may use the same driver.

The one or more host computers may include an administrative computer 103. The administrative computer 103 may be coupled to a management server 110 directly, or via the network 108. The administrative computer 103 may include the software 208, as discussed in more detail below.

FIG. 3 illustrates a peripheral server manager (PSM) 350 and a peripheral driver manager (PDM) 360 coupled through a communication link 370, in an example embodiment. The PSM and the PDM may be installed as the software 208 on the administrative computer 103 and/or the management server 110. The PSM 350 can be used to manage one or more of the client servers 106. Server 106A may manage one or more queues 109, such as PQ1, PQ2, and PQ3, which are associated with driver 316A, in an example embodiment, and may also manage PQ4 and PQ5, which are associated with driver 316B. Server 106B can also manage one or more queues 109, such as PQ6 and PQ7, which is associated with driver 316F. Each print queue 109 may be associated with the same driver, or may be associated with different drivers, in an example embodiment.

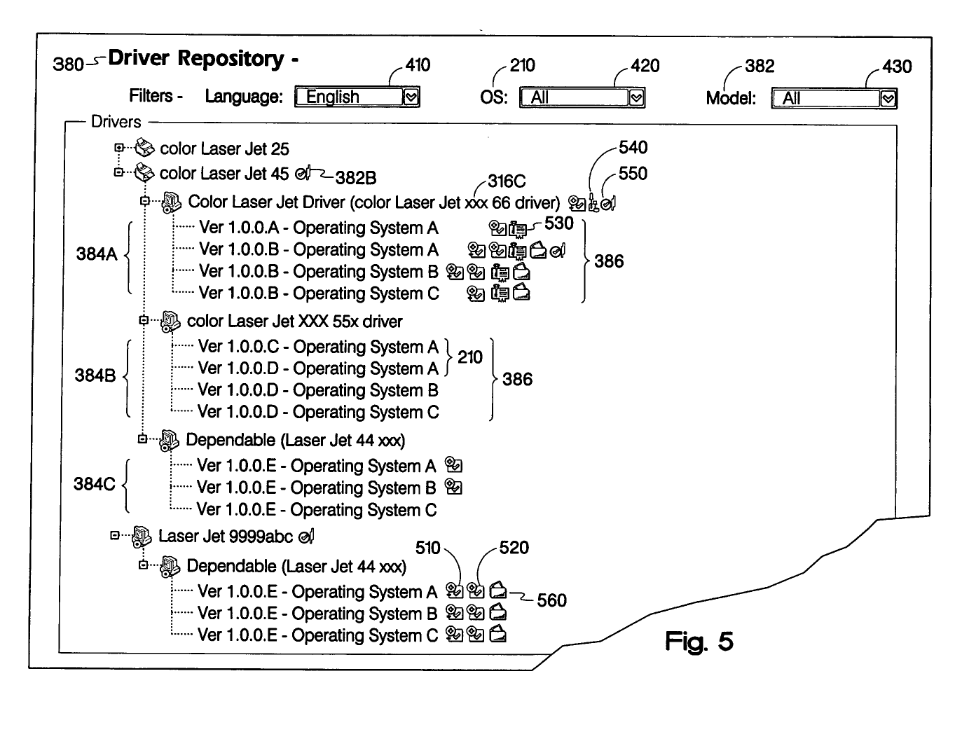

The PSM 350 may manage the print server and communicate with the PDM 360 to update the drivers, for example. The PDM 360 includes a driver repository 380, in an embodiment. A Driver Management Configuration (DMC) 390 may be included in the PDM 360. In some embodiments, the driver management configuration 390 is included in the PSM 350. The driver management configuration 390 is discussed in detail with respect to the pre-configured driver icon 540 illustrated in FIG. 5.

The PDM 360 maintains, collects and organizes one or more drivers. The PDM 360 may indicate that the driver 316A has a newer version to be installed. Accordingly, the PSM 350 may download and install a newer version of 316A, if desired.

The driver repository 380 may include metadata. The metadata can provide a consistent view of the driver data that is accessible to other applications and management tools.

The driver repository 380 comprises means for modeling the model peripheral server system in an embodiment where the model peripheral server system may be constructed, viewed, and amended within the driver repository. The driver repository 380 may include a list of one or more peripheral types, such as peripheral types 382A and 382B, which may include, for example, a printer model such as an HP® color LaserJet 2500. Each of the peripheral types 382A, 382B, and 382C may include one or more associated drivers 316.

Each driver 316 may form part of a driver family 384, which is a collection of the different operating systems 210 and/or different driver versions 386. The operating system (OS) for one or more drivers in the repository 380 may correspond to the operating system 210 of the host computer. In some embodiments, the OS 210 of the host computer may be installed on the corresponding print server. In some cases, a driver may be installed on the print server to support clients that use operating systems other than the OS 210 associated with the host computer.

The peripheral type 382A may include the driver family 384A, and the driver family 384B. The driver family 384A may include one or more drivers. The driver family 384B may also include one or more drivers 316. The driver family 384B may include a driver version 386C and a driver version 386D, each for operating system 210C, in an example embodiment. Also, the driver family 384B may include a driver version 386E for operating system 210D and a driver version 386F for operating system 210E, in an example embodiment. Each driver in a driver family may have the same driver name. If the name of a driver in a first driver family is changed in the repository, the driver may no longer be considered to form a part of the first driver family.

The peripheral type 382B may include the driver family 384C, the driver family 384D, and the driver family 384E. The driver families 384C, 384D and 384E each may include one or more drivers

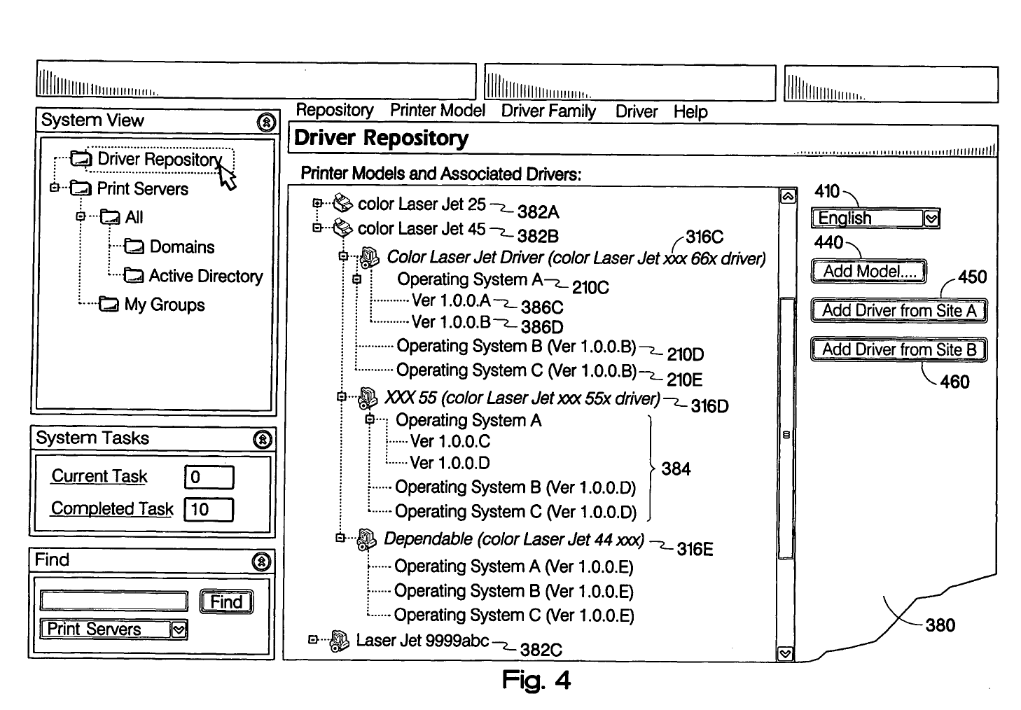

FIGS. 4 and 5 each illustrate example embodiments of a driver repository 380. The driver repository 380 may comprise a model peripheral infrastructure system or model peripheral server setup, for example. The driver repository 380 may also comprise a selected system or setup designed by the administrator.

The driver repository 380 in the illustrated embodiment is shown as a tree hierarchy. The top level includes the peripheral type 382. There may be one or more peripheral types listed in the driver repository, such as types 382A, 382B and 382C. Each peripheral type may include one or more driver families 384. In the illustrated embodiment, each driver family 384 may include a friendly name and a manufacturer's name in parenthesis, such as Color LaserJet Driver (color Laser Jet xxx 66x driver) 316C. Names associated with the driver friendly name and the manufacturer's name may be obtained from hardware discovery. The user may assign the friendly name, if desired. In the illustrated embodiment, drivers 316C, 316D, and 316E are each associated with their own driver family.

Listed under the driver friendly name and the manufacturer's name may be one or more operating systems 210 associated with the driver of the family. Each operating system 210 may include one or more driver versions 386. In some embodiments, the driver family may list the versions separately under the family name, as shown in the embodiment of FIG. 5.

In the embodiment of FIG. 4, the driver 316C may include operating system A 210C, which may include version 1.0.0.A 386C and version 1.0.0.B 386D. The driver 316C may also include operating system B 210D, which may include version 1.0.0.B. The driver 316C may also include operating system C 210E, which may include version 1.0.0.B. In the embodiment of FIG. 4, the driver 316D may include operating system A, which may include version 1.0.0.C and version 1.0.0.D. The driver 316D may also include operating system B, which may include version 1.0.0.D. The driver 316D may also include operating system C, which may include version 1.0.0.D. The driver 316E may also include operating system A, operating system B, and operating system C, each of which may include a version 1.0.0.E.

The peripheral type 382 may be displayed in the driver repository 380 when the corresponding driver 316 is added to the repository. The repository may store the driver 316 as associated with one or more peripheral types 382.

The driver repository 380 may include one or more filters in the embodiments shown in FIGS. 4 and 5. The repository 380 may include a language filter 410, an operating system (OS) filter 420, and a peripheral type (model) filter 430. The language filter 410 may operate to filter the drivers to separately list the drivers associated with the chosen language, such as English. The OS filter 420 may operate to filter the drivers to separately list the drivers associated with the chosen OS, such as Windows® 98 or Windows® NT. The peripheral type filter 430 may operate to filter the drivers to separately list the drivers associated with the chosen peripheral type, such as LaserJet or Inkjet or LaserJet 4500.

In some embodiments, the driver repository 380 may include one or more buttons. The repository 380 may include a button 440 to add a peripheral type (model) to the repository. In some embodiments, the repository 380 includes a button 450 to add a driver from a Site A, such as from UNC. The repository 380 may include a button 460 to add a driver from a Site B, such as from a website, such as from www.hp.com.

In some embodiments, the driver repository 380 may include one or more icons. A default driver icon 510 may indicate which of two possible drivers is chosen as the default driver to use and/or install. Two or more driver versions 386 for each operating system 210 of each driver family may be available. As illustrated in the embodiment of FIG. 5, the peripheral type 316C includes two driver versions for Operating System A. In the example, driver version Ver 1.0.0.B is indicated as the default driver for Operating System A as shown by the associated default driver icon 510. In some embodiments, the default driver icon 510 may cascade up each level in the tree hierarchy, such that the icon 510 is located adjacent the associated driver family name (manufacturer's name). The peripheral type may include a default driver for each associated operating system, for example, driver version Ver 1.0.0.B is indicated as the default driver for the Operating System B and driver version Ver 1.0.0.B is indicated as the default driver is indicated as the default driver for the Operating System C. The first driver added to the repository 380 may be the default driver. In an embodiment illustrated in FIG. 5, the default drivers for one peripheral type 382B each come from the same driver family 384A.

The repository 380 may include a qualified driver icon 520 illustrated in FIG. 5. The qualified driver icon 520 may be used to indicate that the driver associated with the icon has been tested, has passed the test(s), and may be used. The testing may include testing of each driver-peripheral pair, because certain drivers may cause problems with certain software programs or peripheral devices. In some embodiments, the same driver may be qualified for use on one peripheral type, but not another peripheral type.

The repository 380 may include a signed driver icon 530 illustrated in FIG. 5. A signed driver icon 530 may verify authenticity of the associated driver. In verification of authenticity, the driver may be inspected for tampering.

The repository 380 may include a pre-configured driver icon 540 illustrated in FIG. 5. The pre-configured driver icon 540 may be associated with each driver that supports advanced pre-configured driver settings. The driver may be capable of configuration, such as DMC 390. In an example embodiment, the DMC may be used to configure driver operation. The DMC 390 may permit configuration of basic and/or advanced driver settings. The driver may be pre-configured in the repository 380 before it is installed or downloaded onto the host computer. Each driver that is downloaded onto a host computer may be configured differently by the DMC 390. Also, the same driver that is downloaded onto different host computers may be configured differently. Driver settings that are pre-configured may include any number of parameters, such as whether the peripheral associated with the driver prints only in black & white, or prints with three (3) copies each time the peripheral prints, for example. Some host computers are able to print in color to a specific printer, while other host computers are only able to print in black & white to the same specific printer, in an example embodiment. In some embodiments, the pre-configured driver icon 540 may cascade up each level in the tree hierarchy, such that the icon 540 may be located adjacent the associated driver family name (manufacturer's name).

The repository 380 may include an update driver icon 550, as illustrated in the embodiment of FIG. 5. When there is an available new version of the driver or a completely new driver, the update driver icon 550 may be positioned adjacent the most up-to-date version in the driver family. The update driver icon 550 may cascade up each level in the tree hierarchy, such that the update driver icon 550 is located adjacent the associated driver family name (manufacturer's name), and located adjacent the associated peripheral type 382.

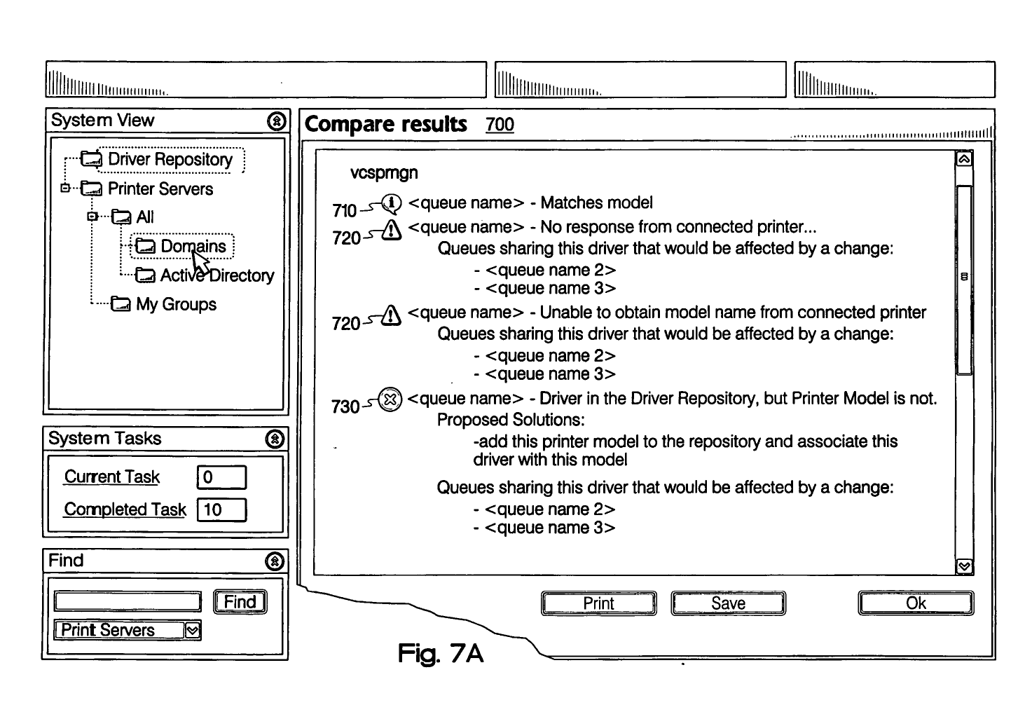

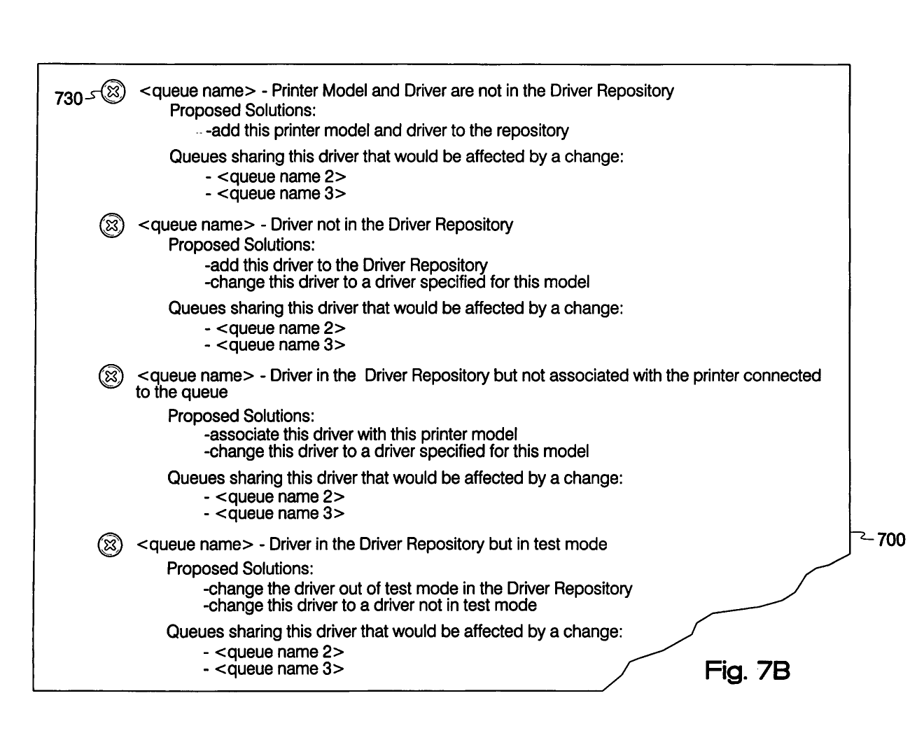

When the update driver icon 550 is activated, and before the driver is updated, the driver repository may indicate whether any jobs in any queues are affected. A queue indicator (not shown), such as a pop-up alert, may respond to the update driver icon 550 to indicate any affected jobs in the queue related to updating the particular driver(s). The queue indicator may be shown in a manner similar to the comparison results 700 illustrated in the analogous embodiment of FIG. 7, as described in more detail herein. Thus, in some embodiments, the system administrator is able to make a more informed decision whether or not to affect the queue by installing the upgrade or driver.

The repository 380 may include a shared driver icon 560, as illustrated in the embodiment of FIG. 5. When the driver in the repository is available to be shared among host computers 102 and/or servers 106, the shared driver icon 560 may be associated with the driver in the repository. The repository 380 may be secure, and access to the repository may be limited. However, there are several ways that the driver may be shared. For example, the driver may be selected in the repository as ‘accessible’ to be shared among host computers and/or servers. The driver may also be shared through an accessible file system, such as UNC share. In some embodiments, the repository 380 may share the driver by allowing access to a web page with a downloadable link for the driver.

The repository 380 may include any number of pull-down menus, drag-drop features, buttons, and icons to associate one or more drivers with one or more peripheral types. In some embodiments, both the driver and the peripheral type may be located in the driver repository, but not yet associated with each other until the menu, feature, button, or icon is appropriately activated.

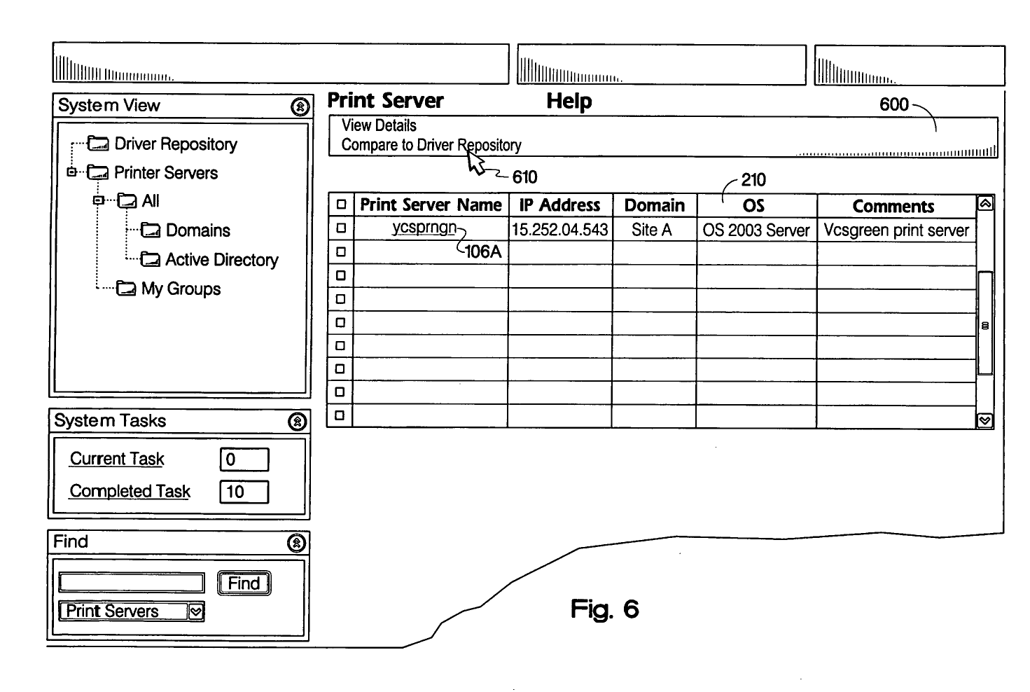

FIG. 6 illustrates a server management page 600 associated with the Peripheral Server Management 350 in an example embodiment. The server management page 600 may provide a list of the peripheral servers 106, such as server 106A, and information associated with the server, including operating system 210 and queue information. In an example embodiment, the server management page 600 includes a drop down menu 610 having a compare indicator, such as a ‘compare to driver repository’ button or indicator. When the compare indicator of the menu 610 is activated, the driver repository 380 may be compared to the current enterprise system (the actual peripheral server setup). Activating the compare indicator 610 on the server management page 600 may be a means for comparing the current and model systems. The means for comparing may comprise a software program in some embodiments.

FIGS. 7A and 7B illustrate an example embodiment of a results comparison page 700, which may include results of comparing the current peripheral server system and the driver repository (the selected peripheral server system). The page 700 may include a results comparison user interface responsive to the compare indicator 610. The results comparison user interface may include selectable solutions to overcome caution symbols 720 or warning symbols 730 as described below.

The page 700 may include one or more indicators associated with different outcome scenarios or results. In an example embodiment, the page 700 may include a successful symbol 710, which indicates that the current system matches the selected or model system. In an example embodiment, the page 700 may include a caution symbol 720, which indicates that the current system may not match the model system. Examples of when caution is indicated include when there is no response from the peripheral, when the manufacturer's name of the peripheral was not obtained in the comparison, or when the current system may match the model system in the comparison, but verification may be lacking.

In an example embodiment, the page 700 includes a warning symbol 730, which indicates that the current system does not match the model system. Where the current system does not match the model system, the two systems are identified as out-of-sync. Areas in the current enterprise system that may be out-of-sync with the model peripheral infrastructure system may include one or more of the following: a driver is not installed in the model peripheral infrastructure system, a current peripheral type is not associated with the model peripheral infrastructure system, the installed driver is not associated with a peripheral type, and the installed driver does not have a qualified driver icon, among others.

For the comparisons where the result is a caution symbol 720 or a warning symbol 730, the results page 700 may list queues that are potentially affected when selected changes are made to either the model system or the current system.

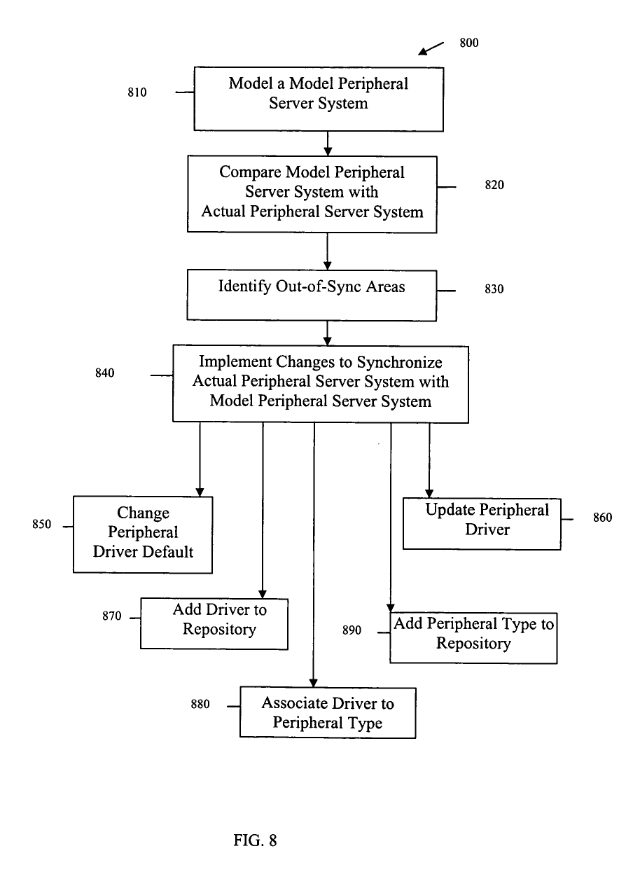

FIG. 8 illustrates an example embodiment of a process 800 to compare a model peripheral server system and an actual peripheral server system. At block 810, a model peripheral server system is modeled. For example, the driver repository 380 may be associated with the model peripheral server system 810. The peripheral types, the drivers for each peripheral type, and the drivers for each operating system and version may be set up in the repository.

At block 820, the model peripheral server system is compared to an actual peripheral server system, which may be associated with the PSM 350. At block 830, out-of-sync areas may be identified using the results of the comparison at block 820. In an example embodiment, the out-of-sync areas refer to areas in which the current system may not match the model system, as discussed herein with respect to FIG. 7. In some embodiments, block 830 may represent means for identifying out-of-sync areas between the current peripheral server system and the model peripheral server system.

At block 840, changes may be implemented to synchronize the current peripheral server system with the model peripheral server system. In some embodiments, blocks 840-890 may represent means for implementing changes to the actual peripheral server system and/or to the model peripheral server system. Blocks 850-890 illustrate a few of many possible changes.

For example, at block 850, a change may be implemented by appropriately changing the peripheral driver default. This may be accomplished in some embodiments where a feature in the page 700, such as a link associated with the default driver icon 510, is activated to change the default driver.

At block 860, a change may be implemented by updating the appropriate peripheral driver. This may be accomplished in some embodiments where a feature in the page 700, such as a link associated with the update driver icon 550, is activated to update the appropriate driver.

At block 870, a change may be implemented by adding an appropriate driver to the repository 380. This may be accomplished in some embodiments where a feature, such as a link associated with the update driver icon 550, is activated to add the appropriate driver.

At block 880, a change may be implemented by appropriately associating a driver to the peripheral type. This may be accomplished in some embodiments where a feature in the comparison result page is activated to add the appropriate driver.

At block 890, a change may be implemented by adding an appropriate peripheral type to the repository 380. This may be accomplished in some embodiments where a feature, such as button 440, is activated to add the appropriate peripheral type.

Many additional changes may be affected. For example, in some embodiments a feature in the page 700 associated with the qualified driver icon 520 can be activated to test and qualify at least one driver, as appropriate to synchronize the systems. In some embodiments, a feature in the page 700 associated with the pre-configured driver icon 540 may be activated to pre-configure one or more settings of at least one driver, as appropriate to synchronize the systems. In addition, a feature in the page 700 associated with an associate driver icon may be activated to associate at least one driver with one of the plurality of peripheral types, as appropriate to synchronize the systems.

The following description includes terms, such as “up”, “down”, “upper”, “lower”, “first”, “second”, etc. that are used for descriptive purposes only and are not to be construed as limiting. The embodiments of a device or article described herein can be manufactured, used, or shipped in a number of positions and orientations.

The functions or algorithms described herein may be implemented in hardware, software or a combination of software and hardware in one embodiment. The software may comprise computer executable instructions stored on computer readable media such as memory or other types of storage devices. The phrases “computer-readable media” or “machine-readable media” may be used to represent software-transmitted carrier waves. Further, such functions correspond to modules, which may be software, hardware, firmware, or any combination thereof. Multiple functions can be performed in one or more modules, and the embodiments described are merely examples. A digital signal processor, application specific integrated circuit (ASIC), microprocessor, or any other type of processor operating on a system, such as a personal computer, server, a router, or any other device capable of processing data including network interconnection devices may be used to execute the software.

Some embodiments implement functions in two or more specific interconnected hardware modules or devices with related control and data signals communicated between and through the modules, or as portions of an application-specific integrated circuit. Thus, the example process flow is applicable to software, firmware, and hardware implementations.

The illustrations of embodiments described herein are intended to provide a general understanding of the structure of various embodiments, and they are not intended to serve as a complete description of all the elements and features of apparatus and systems that might make use of the structures described herein. The accompanying drawings that form a part hereof show by way of illustration, and not of limitation, specific embodiments in which the subject matter may be practiced.

FIGS. 1 to 8 are merely representational and may not be drawn to scale. Certain proportions thereof may be exaggerated, while others may be minimized. Many other embodiments will be apparent to those of skill in the art upon reviewing the above description. Parts of some embodiments may be included in, or substituted for, those of other embodiments. While the foregoing examples of dimensions and ranges are considered typical, the various embodiments are not limited to such dimensions or ranges.

The elements, materials, geometries, dimensions, and sequence of operations can all be varied to suit particular applications. Parts of some embodiments may be included in, or substituted for, those of other embodiments. Applications that may include the apparatus and systems of various embodiments broadly include a variety of electronic and computer systems.

Embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The Abstract is provided to comply with 37 C.F.R. § 1.72(b) to allow the reader to quickly ascertain the nature and gist of the technical disclosure. The Abstract is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments have more features than are expressly recited in each claim. Thus the following claims are hereby incorporated into the Detailed Description, with each claim standing on its own as a separate embodiment.

It will be readily understood to those skilled in the art that various other changes in the details, material, and arrangements of the parts and method stages which have been described and illustrated in order to explain the nature of embodiments herein may be made without departing from the principles and scope of embodiments as expressed in the subjoined claims.

What is claimed is:

1. A driver repository for peripheral management comprising:
a list of a plurality of peripheral types;
a list of at least one driver associated with selected ones of the plurality of peripheral types; and
an icon associated with at least one of the plurality of peripheral types and the at least one driver.

2. The driver repository of claim 1 wherein the icon comprises an update driver icon associated with the at least one driver when an update is available.

3. The driver repository of claim 2 wherein the available update includes a new version of the at least one driver or a new driver.

4. The driver repository of claim 1 further comprising a queue indicator to indicate when there are jobs in a queue for a peripheral associated with the queue indicator.

5. The driver repository of claim 4 wherein the queue indicator responds to an update driver icon.

6. The driver repository of claim 1 wherein the icon comprises a default driver icon associated with the at least one driver for the selected ones of the plurality of peripheral types.

7. The driver repository of claim 1 wherein the icon comprises a qualified driver icon associated with the at least one driver that has been tested.

8. The driver repository of claim 1 wherein the icon comprises a signed driver icon associated with the at least one driver to verify authenticity of the at least one driver.

9. The driver repository of claim 1 wherein the icon comprises a shared driver icon associated with the at least one driver that is available to share.

10. The driver repository of claim 1 wherein the icon comprises a pre-configured driver icon associated with each driver that supports advanced pre-configured driver settings.

11. The driver repository of claim 1, further comprising a language filter to separately list drivers associated with a pre-determined language.

12. The driver repository of claim 1, further comprising an operating system filter to separately list drivers associated with a pre-determined operating system.

13. The driver repository of claim 1, further comprising a type filter to separately list drivers associated with a pre-determined peripheral type.

14. A peripheral management system, comprising:
a peripheral type; and
a peripheral driver family including a plurality of drivers associated with the peripheral type, wherein selected ones of the plurality of drivers are associated with at least one of a different operating system for the peripheral driver and a different version for the peripheral driver.

15. The system of claim 14 wherein the peripheral type, the peripheral driver family, and one of the selected ones of the plurality of drivers has an update driver icon when the one of the selected ones of the plurality of drivers has an available update.

16. The system of claim 14, further comprising a server having a queue for a peripheral associated with the peripheral type.

17. The system of claim 16, wherein one of the plurality of drivers has an update driver icon to indicate a corresponding available update, wherein a queue indicator responds to the update driver icon to inform of an ability to update one of the plurality of drivers.

18. A peripheral management system, comprising:
a model peripheral infrastructure system;
a current enterprise system; and
an identification of at least one area in the current enterprise system that is out-of-sync with the model peripheral infrastructure system.

19. The system of claim 18, wherein the model peripheral infrastructure system includes a driver repository listing a plurality of peripheral types and at least one driver associated with selected ones of the plurality of peripheral types.

20. The system of claim 19, wherein the at least one area includes at least one indication of the driver is not installed in the model peripheral infrastructure system, one of the plurality of peripheral types is not indicated as associated with the model peripheral infrastructure system, the driver is installed and not associated with the one of the plurality of peripheral types, and the driver is installed and does not have a qualified driver icon.

21. A peripheral management system comprising:
a current peripheral server system;
means for modeling a model peripheral server system, wherein the model peripheral server system includes a plurality of peripheral types and at least one driver associated with selected ones of the plurality of peripheral types; and
means for comparing the current peripheral server system and the model peripheral server system.

22. The system of claim 21, wherein the model peripheral server system includes a driver repository listing the plurality of peripheral types and the at least one driver associated with selected ones of the plurality of peripheral types.

23. The system of claim 21, further comprising a user interface with a compare indicator, wherein the means for comparing the model peripheral server system and the current peripheral server system includes the compare indicator.

24. The system of claim 22, further comprising:
means for identifying out-of-sync areas between the current peripheral server system and the model peripheral server system; and
means for implementing changes to the model peripheral server system and the current peripheral server system to synchronize the model peripheral server system and the current peripheral server system.

25. The system of claim 24 wherein the out-of-sync areas include at least one of the drivers is not installed in the driver repository, one of the plurality of peripheral types is not indicated as associated with the driver repository, a driver is installed and not associated with the one of the plurality of peripheral types, and a driver is installed and does not have a qualified driver icon.

26. The system of claim 24 wherein the means for identifying out-of-sync areas include a results comparison user interface responsive to the means for comparing, wherein the means for implementing changes to the current peripheral server system to synchronize the current peripheral server system with the model peripheral server system includes an update driver icon to update the at least one driver, a default driver icon to change a peripheral driver default, a qualified driver icon to test and qualify the at least one driver, an install driver icon, a pre-configured driver icon to pre-configure a setting associated with the at least one driver, and an associate driver icon to associate the at least one driver with one of the plurality of peripheral types.

27. An article including a machine-accessible medium having associated information, wherein the information, when accessed, results in a machine performing:
managing of at least one peripheral, including modeling a model peripheral infrastructure system and comparing the model peripheral infrastructure system and a current enterprise system,
wherein the model peripheral infrastructure system includes a driver repository listing a plurality of peripheral types included in the model peripheral infrastructure system and at least one driver associated with selected ones of the plurality of peripheral types.

28. The article of claim 27, further comprising:
identifying out-of-sync areas between the current enterprise system and the model peripheral infrastructure system; and
implementing changes to at least one of the model peripheral infrastructure system and a current enterprise system to synchronize the current enterprise system and the model peripheral infrastructure system.

29. The article of claim 27, wherein the implementing changes includes at least one of:
updating at least one driver associated with selected ones of a plurality of peripheral types included in the current enterprise system;
changing a default of the at least one driver associated with the selected ones of the plurality of peripheral types included in the current enterprise system;
testing and qualifying the at least one driver associated with the selected ones of the plurality of peripheral types included in the model peripheral infrastructure system;
installing the at least one driver in at least one of the model peripheral infrastructure system and the current enterprise system;
pre-configuring a setting associated with the at least one driver in the model peripheral infrastructure system; and
associating the at least one driver in the model peripheral infrastructure system with one of the plurality of peripheral types in at least one of the model peripheral infrastructure system and the current enterprise system.

30. A peripheral management method comprising:
modeling a model peripheral infrastructure system; and
comparing the model peripheral infrastructure system and a current enterprise system,
wherein the model peripheral infrastructure system includes a driver repository listing a plurality of peripheral types included in the model peripheral infrastructure system and at least one driver associated with selected ones of the plurality of peripheral types.
